(19) United States
(12) Patent Application Publication
(10) Pub. No.: US 2025/0218731 A1
(43) Pub. Date: Jul. 3, 2025

(54) SHOWERHEAD AND SUBSTRATE TREATMENT APPARATUS INCLUDING SHOWERHEAD

(71) Applicant: SEMES CO., LTD., Cheonan-si (KR)

(72) Inventor: Je Ho KIM, Hwaseong-si (KR)

(21) Appl. No.: 18/933,004

(22) Filed: Oct. 31, 2024

(30) Foreign Application Priority Data
Dec. 27, 2023 (KR) 10-2023-0193573

(51) Int. Cl. H01J 37/32

(52) U.S. Cl. CPC H01J 37/32449; H01J 2237/002; H01J 2237/24585; H01J 2237/3341

(57) ABSTRACT

A showerhead spraying a processing gas for treating a substrate into a treatment space of a processing chamber, the showerhead includes a shower plate in which a plurality of spray holes are formed, the shower plate configured to spray a processing gas into the treatment space through the plurality of spray holes, a lower plate installed on an upper side of the shower plate, the lower plate in which a plurality of spray flow paths, connected to the plurality of spray holes, are formed, an upper plate installed on an upper side of the lower plate, the upper plate configured to spray the processing gas to the plurality of spray flow paths, and a planar heating element configured to heat the processing gas sprayed through the shower plate.

### CROSS-REFERENCE TO RELATED APPLICATION(S)

This application claims benefit of priority to Korean Patent Application No. 10-2023-0193573 filed on Dec. 27, 2023 in the Korean Intellectual Property Office, the disclosure of which is incorporated herein by reference in its entirety.

### BACKGROUND

### 1. Field

The present disclosure relates to a showerhead and a substrate treatment apparatus including the same.

### 2. Description of Related Art

When a predetermined pattern is formed on a substrate, various unit processes, such as a deposition process, a lithography process, and an etching process, may be performed continuously in a facility used for a semiconductor manufacturing process.

Among such processes, the etching process may be a process of removing a film formed on the substrate, and the etching process may be classified as a wet etching process or a dry etching process, depending on a processing method.

Among such processes, in the dry etching process, the film formed on the substrate may be etched using plasma in a processing chamber, and a showerhead may be used to supply a processing gas for etching the substrate (for example, a wafer).

The showerhead may include a heating member and a cooling member such that the substrate may maintain a process temperature when the etching process is being performed. Among the members, the heating member may be positioned on the outside of an electrostatic chuck, and the cooling member may be formed on the inside of the heating member with respect to the electrostatic chuck. Due to such a structure, uniform temperature distribution of the showerhead may not be maintained.

### SUMMARY

An aspect of the present disclosure provides a showerhead capable of maintaining uniform temperature distribution thereof, the showerhead having excellent heat dissipation properties and thermal conductivity, and a substrate treatment apparatus including the same.

According to an aspect of the present disclosure, there is provided a showerhead spraying a processing gas for treating a substrate into a treatment space of a processing chamber, the showerhead includes a shower plate in which a plurality of spray holes are formed, the shower plate configured to spray a processing gas into the treatment space through the plurality of spray holes, a lower plate installed on an upper side of the shower plate, the lower plate in which a plurality of spray flow paths, connected to the plurality of spray holes, are formed, an upper plate installed on an upper side of the lower plate, the upper plate configured to spray the processing gas to the plurality of spray flow paths, and a planar heating element configured to heat the processing gas sprayed through the shower plate.

The planar heating element may be a material in which graphene and graphite particles are mixed at a weight ratio of 1:2 to 8, and a size ratio of the graphene to the graphite particles may be 1:30 to 2000.

The planar heating element may have a thickness of 0.1 mm or more and 0.2 mm or less.

The planar heating element may be provided in at least one of a space between the shower plate and the lower plate and a space between the lower plate and the upper plate.

The planar heating element may have a shape corresponding to a shape of a surface on which the shower plate and the lower plate are in contact with each other or a shape corresponding to a shape of a surface on which the lower plate and the upper plate are in contact with each other.

A plurality of through-holes may be formed in the planar heating element, and the number of the plurality of through-holes may be formed to respectively correspond to the number of the plurality of spray holes or the plurality of spray flow paths.

The showerhead may further include a power supply configured to operate the planar heating element as a heat dissipating element by supplying power to the planar heating element.

The showerhead may further include at least one temperature measuring unit passing through the lower plate and the upper plate, the at least one temperature measuring unit installed on the shower plate, the at least one temperature measuring unit configured to measure a temperature of the shower plate.

The showerhead may further include a controller configured to control, based on the temperature of the shower plate measured by the temperature measuring unit, a temperature of the planar heating element through the power supply.

The controller may be configured to control the power supply to maintain a uniform temperature of the planar heating element.

The planar heating element may be configured to operate as a heat conductor, when power supplied from the power supply is cut off.

A cooling flow path through which a refrigerant flows for preventing the shower plate from being heated to a temperature higher than or equal to a limit temperature may be formed in the upper plate.

The single flow path may be formed to have a curved shape along an edge region of the upper plate in the edge region, may be formed to have a circular shape along a boundary between the edge region and a middle region of the upper plate at the boundary, may be formed to have a curved shape along the middle region of the upper plate in the middle region, may be formed to have a circular shape along a boundary between the middle region and a center region of the upper plate at the boundary, and may be formed to have a circular shape in the center region of the upper plate.

According to another aspect of the present disclosure, there is provided a showerhead spraying a processing gas for treating a substrate into a treatment space of a processing chamber, the showerhead including a shower plate in which a plurality of spray holes are formed, the shower plate configured to spray a processing gas into the treatment space through the plurality of spray holes, a lower plate installed on an upper side of the shower plate, the lower plate in which a plurality of spray flow paths, connected to the plurality of spray holes, are formed, an upper plate installed on an upper side of the lower plate, the upper plate configured to spray the processing gas to the plurality of spray flow paths, a planar heating element configured to heat the processing gas sprayed through the shower plate, a power supply configured to operate the planar heating element as a heat dissipating element by supplying power to the planar heating element, at least one temperature measuring unit passing through the lower plate and the upper plate, the at least one temperature measuring unit installed on the shower plate, the at least one temperature measuring unit configured to measure a temperature of the shower plate, and a controller configured to control, based on the temperature of the shower plate measured by the temperature measuring unit, a temperature of the planar heating element through the power supply. The planar heating element may have a shape corresponding to a shape of a surface on which the shower plate and the lower plate are in contact with each other or a shape corresponding to a shape of a surface on which the lower plate and the upper plate are in contact with each other.

The planar heating element may be a material in which graphene and graphite particles are mixed at a weight ratio of 1:2 to 8, and a size ratio of the graphene to the graphite particles may be 1:30 to 2000.

The planar heating element may have a thickness of 0.1 mm or more and 0.2 mm or less.

The planar heating element may be configured to operate as a heat conductor, when power supplied from the power supply is cut off.

According to another aspect of the present disclosure, there is provided a substrate treatment apparatus including a processing chamber in which a treatment space is formed to treat a substrate, a showerhead installed on an upper side of the treatment space in the processing chamber, the showerhead configured to spray a processing gas for treating the substrate into the treatment space, and a substrate support installed on a lower side of the treatment space to vertically oppose the showerhead in the processing chamber, the substrate support on which the substrate is mounted. The showerhead may include a shower plate in which a plurality of spray holes are formed, the shower plate configured to spray the processing gas into the treatment space through the plurality of spray holes, a lower plate installed on an upper side of the shower plate, the lower plate in which a plurality of spray flow paths, connected to the plurality of spray holes, are formed, an upper plate installed on an upper side of the lower plate, the upper plate configured to spray the processing gas to the plurality of spray flow paths, and a planar heating element configured to heat the processing gas sprayed through the shower plate. The planar heating element may be graphene or a graphene-mixed material, and the graphene-mixed material may be a material in which graphene and graphite particles are mixed at a weight ratio of 1:2 to 8, and a size ratio of the graphene to the graphite particles may be 1:30 to 2000. The planar heating element may be provided in at least one of a space between the shower plate and the lower plate and a space between the lower plate and the upper plate.

According to aspects of the present disclosure, uniform temperature distribution of a showerhead may be controlled through a planar heating element instead of a heating member positioned on the outside of an electrostatic chuck.

In addition, according to aspects of the present disclosure, the planar heating element may have excellent heat dissipation properties and thermal conductivity using graphene or a graphene-mixed material.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 illustrates a substrate treatment apparatus including a showerhead according to an example embodiment of the present disclosure;

FIGS. 2A to 2C illustrate a showerhead including a planar heating element provided in various positions according to an example embodiment of the present disclosure;

FIG. 3 illustrates a planar heating element according to an example embodiment of the present disclosure;

FIG. 4 illustrates a cooling flow path provided in an upper plate according to example embodiment of the present disclosure; and

FIG. 5 illustrates a temperature measuring unit, a power supply, and a controller included in a showerhead according to an example embodiment of the present disclosure.

### DETAILED DESCRIPTION

Hereinafter, specific example embodiments of the present disclosure will be described with reference to the accompanying drawings. The following detailed description is provided to aid in a comprehensive understanding of a method, a device and/or a system described in the present specification. However, the detailed description is for illustrative purposes only, and the present disclosure is not limited thereto.

In describing the example embodiments of the present disclosure, when it is determined that a detailed description of a known technology related to the present disclosure may unnecessarily obscure the gist of the present disclosure, the detailed description thereof will be omitted. In addition, terms to be described later are terms defined in consideration of functions in the present disclosure, which may vary depending on intention or custom of a user or operator. Therefore, the definition of these terms should be made based on contents throughout the present specification. The terminology used herein is for the purpose of describing particular example embodiments only and is not to be construed as being limiting of the example embodiments. As used herein, the singular forms “a,” “an,” and “the” are intended to include the plural forms as well, unless the context clearly indicates otherwise. As used herein, the term “and/or” includes any one and any combination of any two or more of the associated listed items. It will be further understood d that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

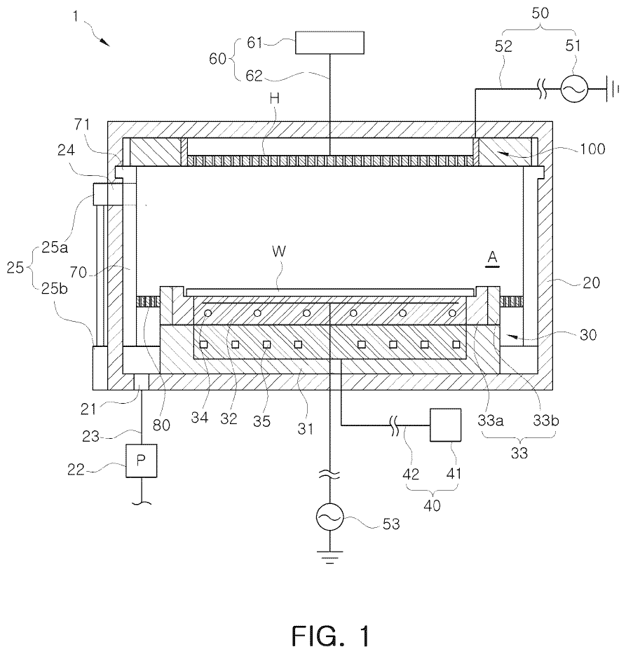

FIG. 1 illustrates a substrate treatment apparatus including a showerhead according to an example embodiment of the present disclosure.

Referring to FIG. 1, a substrate treatment apparatus 1 may include a processing chamber 20, a substrate support 30, a first gas supply unit 40, a plasma generation unit 50, a second gas supply unit 60, a liner (or a wall-liner) 70, and a baffle unit 80.

A substrate treatment system 1 of the present disclosure may be a system, treating a substrate W using a dry etching process, and may treatment the substrate W using, for example, a plasma process.

As illustrated in FIG. 1, the processing chamber 20 may have a treatment space A in which the substrate W is treated, and thus a plasma process may be performed in the treatment space A.

In addition, an exhaust hole 21 may be formed in a lower portion of the processing chamber 20. The exhaust hole 21 may be connected to the exhaust line 23 on which the pump 22 is mounted, and the exhaust hole 21 may discharge reaction by-products generated during a plasma process and gas remaining in the processing chamber 20 to the outside of the processing chamber 20 through the exhaust line 23. In this case, the treatment space A of the processing chamber 20 may be decompressed to a predetermined pressure.

In addition, a gate 24 may be formed on a sidewall of the processing chamber 20. The gate 24 may function as a passage through which the substrate W enters and exits the treatment space A of the processing chamber 20, and may be configured to be opened and closed by a door assembly 25.

For example, the door assembly 25 may include a door body 25a and a door driver 25b. More specifically, the door body 25a may be formed in a position corresponding to that of the gate 24 on an outer wall of the processing chamber 20. The door body 25a may be moved in a vertical direction (a height direction of the processing chamber 20) by the door driver 25b. The door driver 25b, driving the door body 25a, may be a combination of a motor and a gear, or any type of driving apparatus capable of reciprocating the door body 25a, such as a pneumatic cylinder, an electric cylinder, and a hydraulic cylinder, on a precedent basis.

The substrate support 30 may be installed on a lower side of the treatment space A so as to vertically oppose a showerhead 100 to be described below in the processing chamber 20, and the substrate W may be mounted on an upper surface thereof. The substrate support 30 may support the substrate W using electrostatic force so as to effectively support the substrate W in the treatment space A in a vacuum atmosphere. However, a method in which the substrate W supported by the substrate support 30 is not necessarily limited thereto, and may be various methods such as mechanical clamping, vacuum, and the like.

As in the present disclosure, when the substrate W is supported using an electrostatic force, the substrate support 30 may include a base 31 and an electrostatic chuck 32.

For example, the electrostatic chuck 32 may support the substrate W, mounted on an upper surface thereof, using electrostatic force, and may be formed of a ceramic material, and thus may be coupled to the base 31 so as to be fixed to the base 31.

In addition, the electrostatic chuck 32 may be installed to be movable in the vertical direction (the height direction of the processing chamber 20) in the processing chamber 20, using a driving member (not illustrated). As described, when the electrostatic chuck 32 is formed to be movable in the vertical direction, the substrate W may be positioned in a region exhibiting more uniform plasma distribution.

In addition, the ring assembly 33, having a ring shape, may be formed to surround an edge of the electrostatic chuck 32. The ring assembly 33 having a ring shape may be configured to support an edge region of the substrate W.

The ring assembly 33 may include a focus ring 33a and an insulating ring 33b. For example, the focus ring 33a may be formed on the inside of the insulating ring 33b, and may be formed to surround the electrostatic chuck 32. The focus ring 33a may be formed of a silicon material, and may concentrate plasma on the substrate W. In addition, the insulating ring 33b may be formed to surround the focus ring 33a on the outside the focus ring 33a. The insulating ring 33b may be formed of a quartz material.

In addition, the ring assembly 33 may further include an edge ring formed to be in close contact with an edge of the focus ring 33a. The edge ring may be formed to prevent a side surface of the electrostatic chuck 32 from being damaged by plasma.

The first gas supply unit 40 may supply gas to remove foreign substances remaining on an upper portion of the ring assembly 33 or on an edge portion of the electrostatic chuck 32. The first gas supply unit 40 may include a first gas supply source 41 and a first gas supply line 42.

The first gas supply source 41 may supply a nitrogen gas N₂ as a gas for removing foreign substances. However, the present disclosure is not necessarily limited thereto, and the first gas supply source 41 may supply other gases, a cleaning agent, or the like.

The first gas supply line 42 may be formed between the electrostatic chuck 32 and the ring assembly 33. For example, the first gas supply line 42 may be formed to be connected between the electrostatic chuck 32 and the focus ring 33a. In addition, the first gas supply line 42 may be provided into the focus ring 33a and formed to be bent, such that the first gas supply line 42 may be connected between the electrostatic chuck 32 and the focus ring 33a.

The heating member 34 and the cooling member 35 may be configured such that the substrate W may maintain a process temperature when an etching process is performed in the treatment space A of the processing chamber 20. The heating member 34 may be provided as a heating wire for this purpose, and the cooling member 35 may be provided as a cooling flow path through which a refrigerant flows.

The heating member 34 and the cooling member 35 may be installed on the inside of the substrate support 30 to maintain a process temperature of the substrate W. For example, the heating member 34 may be installed on the inside of the electrostatic chuck 32, and the cooling member 35 may be installed on the inside of the base 31.

The plasma generation unit 50 may generate plasma from a gas remaining in a discharge space. Here, the discharge space may refer to a space of the treatment space A of the processing chamber 20 between the substrate support 30 and the showerhead 100.

The plasma generation unit 50 may generate plasma in the discharge space of the treatment space A of the processing chamber 20, using a capacitively coupled plasma (CCP) source. In this case, the plasma generation unit 50 may use the showerhead 100 as an upper electrode and the electrostatic chuck 32 of the substrate support 30 as a lower electrode.

However, a configuration of the plasma generation unit 50 is not necessarily limited thereto. When plasma is generated in the discharge space using an inductively coupled plasma (ICP) source, an antenna (not illustrated) installed on an upper portion of the processing chamber 20 may be used as an upper electrode, and the electrostatic chuck 32 may be used as a lower electrode.

More specifically, the plasma generation unit 50 may include an upper electrode, a lower electrode, an upper power source 51, and a lower power source 53. In addition, as described above, when the plasma generation unit 50 uses a CCP source, the showerhead 100 may function as an upper electrode, and the electrostatic chuck 32 may function as a lower electrode.

The showerhead 100, functioning as the upper electrode, may be installed to vertically oppose the electrostatic chuck 32, functioning as the lower electrode, in the treatment space A of the processing chamber 100. The showerhead 100 may include a plurality of gas spray holes H for spraying a processing gas into the treatment space A, and may be formed to have a diameter greater than that of the electrostatic chuck 32.

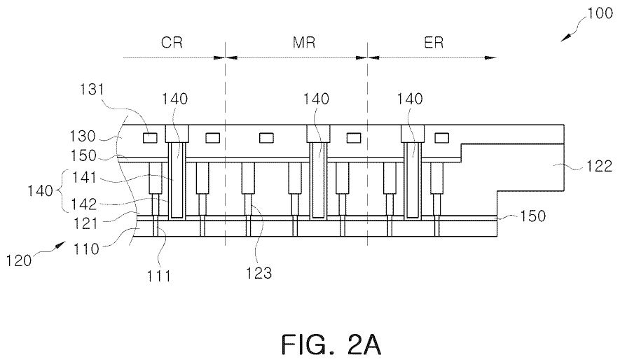

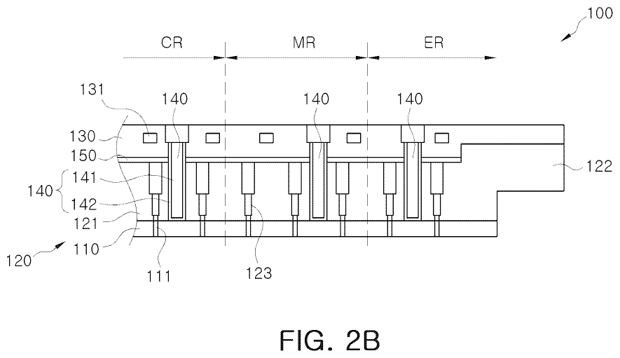

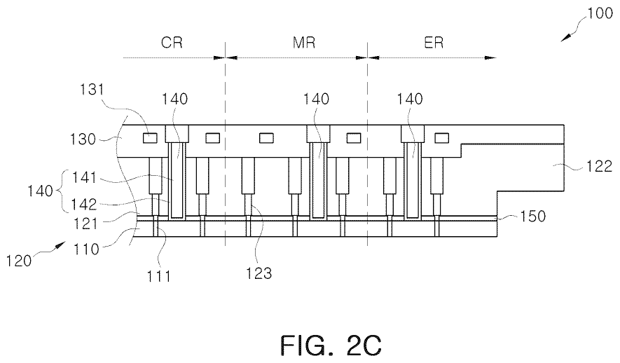

The showerhead 100 may include a temperature measuring unit (see 140 of FIGS. 2A to 2C to be described below) therein, and may be formed of a silicon material or a metal material.

The upper power source 51 may apply power to the upper electrode, that is, the showerhead 100, and may be provided to control properties of plasma. For example, the upper power source 51 may be provided to adjust ion bombardment energy. In addition, a first impedance matching circuit (not illustrated) may be provided on a first transmission line 52, connecting the upper power source 51 to the showerhead 100, for impedance matching.

In addition, the lower power source 53 may apply power to the lower electrode, that is, the electrostatic chuck 32, and may serve as a plasma source generating plasma or may serve to control the properties of plasma, together with the upper power source 51.

The second gas supply unit 60 may supply a processing gas to the treatment space A of the processing chamber 20 through the showerhead 100, and may include a second gas supply source 61 and a second gas supply line 62.

More specifically, the second gas source 61 may supply an etching gas used to treat the substrate W as a processing gas, and may supply a gas (for example, a gas such as SF6, CF4, or the like) including a fluorine component as the etching gas.

In addition, a single second gas supply source 61 may be provided to supply an etching gas to the showerhead 100. However, the present disclosure is not necessarily limited thereto, and a plurality of second gas supply sources 61 may be provided to supply a processing gas to the showerhead 100.

The liner 70 may be provided to protect an internal surface of the processing chamber 20 from arc discharge generated in a process of exciting a processing gas, and impurities generated during a substrate treatment process. The liner 70 may be formed to have a cylindrical shape in which upper and lower portions thereof are opened along the internal surface of the processing chamber 20.

In addition, the liner 70 may include a support ring 71 on an upper portion thereof. The support ring 71 may formed to protrude from the upper portion of the liner 70 in an outward direction (that is, a direction of an external surface of the processing chamber 20), and may be disposed on an upper end of the processing chamber 20 to support the liner 70.

The baffle unit 80 may serve to exhaust process by-products of plasma, unreacted gases, or the like. The baffle unit 80 may be installed between an inner wall of the processing chamber 20 and an external surface of the substrate support 30.

More specifically, the baffle unit 80 may be formed to have an annular ring shape, and a plurality of through-holes, passing through the baffle unit 80 in the vertical direction (the height direction of the processing chamber 20), may be formed. The baffle unit 80 may control a flow of a processing gas according to the number and shape of the through-holes.

Hereinafter, the showerhead 100, included in the substrate treatment apparatus 1 described above, will be described in detail.

FIGS. 2A to 2C illustrate a showerhead including a planar heating element provided in various positions according to an example embodiment of the present disclosure.

That is, FIG. 2A illustrates a planar heating element 150 disposed between a lower plate 120 and an upper plate 130 and between a shower plate 110 and the lower plate 120, FIG. 2B illustrates a planar heating element 150 disposed between a lower plate 120 and an upper plate 130, and FIG. 2C illustrates a planar heating element 150 disposed between a shower plate 110 and a lower plate 120. FIGS. 2A to 2C may be the same in terms of other configurations, except for an arrangement position of the planar heating element 150. Hereinafter, descriptions will be provided based on FIG. 2A.

As illustrated in FIG. 2A, a showerhead 100 may include a shower plate 110, a lower plate 120, an upper plate 130, a temperature measuring unit 140, and a planar heating element 150.

The shower plate 110 may directly spray a processing gas used to treat a substrate W into a treatment space A of a processing chamber 20. To this end, a lower surface of the shower plate 110 may be formed to be exposed to the treatment space A in a vacuum atmosphere.

More specifically, the shower plate 110 having a disk shape may have a plurality of spray holes 111. The shower plate 110 may be divided into a center region CR, a middle region MR, and an edge region ER. In this case, the regions CR, MR, and ER may have the same number of spray holes 111, but may have different numbers of spray holes 111. In addition, the number of regions into which the shower plate 110 are divided is three, but the present disclosure is not necessarily limited thereto. The shower plate 110 may be divided into significantly various numbers of regions according to needs in process.

The lower plate 120 may be installed on an upper side of the shower plate 110, and formed to have a disk shape such as the shape of the shower plate 110, such that a plurality of spray flow paths 123, connected to the plurality of spray holes 111, may be formed. The lower plate 120 may include a plate body 121 and a protrusion 122.

For example, the plate body 121 may have the plurality of spray flow paths, 123 connected to the plurality of spray holes 111, and may have the protrusion 122, having a ring shape, along an outer circumferential surface thereof. The protrusion 122 may be formed to have a ring shape along the outer circumferential surface of the plate body 121, and may be used for coupling between the lower plate 120 and the upper plate 130 to be described below.

In addition, the plurality of spray flow paths 123 of the lower plate 120 and the plurality of spray holes 111 of the shower plate 110 may be connected to each other. To this end, the number of the plurality of spray flow paths 123 may be formed to respectively correspond to the number of the plurality of spray holes 111. In this case, the plurality of spray flow paths 123 may be formed to have a shape having a width gradually decreasing in a downward direction.

The planar heating element 150 may be disposed between the lower plate 120 and the upper plate 130 and between the shower plate 110 and the lower plate 120 to heat a processing gas sprayed through the shower plate 110. According to another example embodiment of the present disclosure, as illustrated in FIG. 2B, the planar heating element 150 may be disposed between the lower plate 120 and the upper plate 130, or as illustrated in FIG. 2C, the planar heating element 150 may be disposed between the shower plate 110 and the lower plate 120.

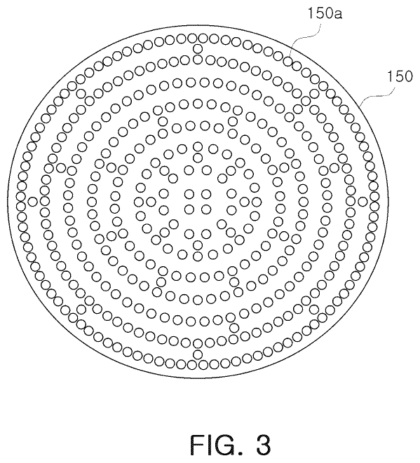

FIG. 3 illustrates a planar heating element 150 according to an example embodiment of the present disclosure.

As illustrated in FIG. 3, the planar heating element 150 may have a shape corresponding to a shape of a surface on which the shower plate 110 and the lower plate 120 are in contact with each other, or may have a shape corresponding to a shape of a surface on which the lower plate 120 and the upper plate 130 are in contact with each other. The planar heating element 150 may have a circular shape.

In addition, a plurality of through-holes 150a may be formed in the planar heating element (150), and the number of the plurality of through-holes 150a may be formed to correspond to the number of the plurality of spray holes 111 or the plurality of spray flow paths 123.

The planar heating element 150 may be graphene or a graphene-mixed material, and the graphene mixed material may be a material in which graphene and graphite particles are mixed in a weight ratio of 1:2 to 8, and a size ratio of the graphene to the graphite particles may be 1:30 to 2000.

That is, the graphene or the graphene-mixed material may have excellent heat dissipation properties and excellent thermal conductivity. Such a material may be used to maintain uniform temperature distribution of a showerhead.

Furthermore, a thickness of the planar heating element 150 may be 0.1 mm or more and 0.2 mm or less. That is, when the thickness of the planar heating element 150 is greater than 0.2 mm, the planar heating element 150 may have a wide variation in thermal conductivity. When the thickness of the planar heating element 150 is less than 0.1 mm, installation or maintenance of the planar heating element 150 may be difficult. Accordingly, in the present disclosure, the thickness of the planar heating element 150 may be set to 0.1 mm or more and 0.2 mm or less in consideration of a variation in thermal conductivity and installation or maintenance of the planar heating element 150.

The upper plate 130 may be installed on the planar heating element 150 such that the upper plate 130 is installed on an upper side of the lower plate 120, and may function to respectively distribute and supply processing gases, introduced from an external source, to the plurality of spray flow paths 123 of the lower plate 120. In addition, the upper plate 130 may include a cooling flow path 131 therein.

For example, the cooling flow path 131 may be provided as a flow path in the upper plate 130 through which cooling water or cooling fluid flows. The cooling flow path 131 may prevent the shower plate 110 from being heated to a temperature higher than or equal to a limit temperature.

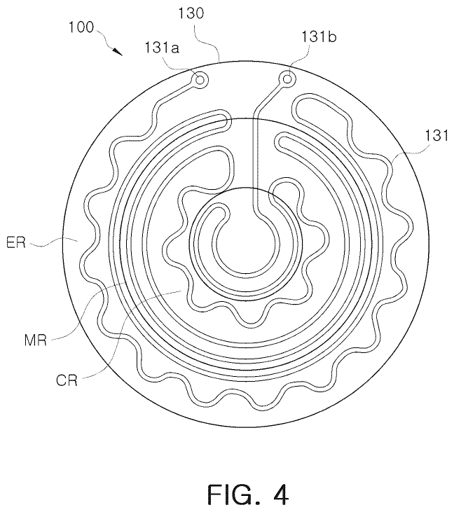

FIG. 4 illustrates a cooling flow path provided in an upper plate according to an example embodiment of this disclosure.

As illustrated in FIG. 4, a cooling flow path 131 may be configured as a single flow path, and may circulate a refrigerant, introduced through a refrigerant inlet 131a, and may then discharge the refrigerant through a refrigerant outlet 131b.

Here, the single flow path 131 may be formed to have a curved shape along an edge region ER of an upper plate 130 in the edge region ER, may be formed to have a circular shape along a boundary between the edge region ER and a middle region MR of the upper plate 130 at the boundary, may be formed to have a curved shape along the middle region MR of the upper plate 130 in the middle region MR, may be formed to have a circular shape along a boundary between the middle region MR and a center region CR of the upper plate 130 at the boundary, and may be formed to have a circular shape in the center region CR of the upper plate 130.

Referring back to FIG. 2A, the temperature measuring unit 140 may include at least one temperature measuring unit passing through the lower plate 120 and the upper plate 130, the at least one temperature measuring unit installed on the shower plate 110, the at least one temperature measuring unit measuring a temperature of a predetermined region of the shower plate 110.

More specifically, the temperature measuring unit 140 may include a temperature sensor 141 formed to pass through the lower plate 120 and the upper plate 130, and a protective bush 142 formed to surround at least a portion of a lower end of the temperature sensor 141, adjacent to the shower plate 110, so as to separate the temperature sensor 141 from a vacuum atmosphere of the treatment space A of the processing chamber 20.

The temperature sensor 141 may be a fiber-optic temperature sensor capable of measuring temperature using an optical fiber.

More specifically, the fiber-optic temperature sensor may be a sensor measuring temperature through direct contact, and various types of sensors, such as a sensor using an optical fiber as a transmission path of light and a sensor using an optical fiber itself as a functional sensor, may be applied.

In addition, the protective bush 142, protecting the temperature sensor 141 so as to separate the temperature sensor 141 from the vacuum atmosphere of the treatment space A of the processing chamber 20, may be preferably formed of a transparent quartz material so as to separate the temperature sensor 141 from the vacuum atmosphere of the treatment space A while being maintained in a state of smoothly performing a function of measuring temperature using light.

Accordingly, the fiber-optic temperature sensor of the temperature sensor 141 may be protected by the protective bush 142 formed of a quartz material, such that the fiber-optic temperature sensor may be separated from the treatment space A that is in a vacuum atmosphere of the processing chamber 20, and may be maintained in a non-vacuum state without being exposed to a processing gas, thereby extending a lifespan of the sensor and inducing the sensor to normally operate in a non-vacuum state, resulting in an increase in accuracy of temperature measurement.

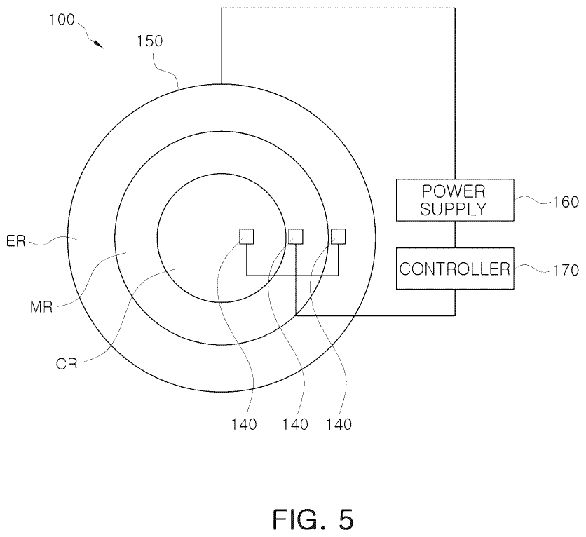

Finally, FIG. 5 illustrates a temperature measuring unit, a power supply, and a controller included in a showerhead according to an example embodiment of the present disclosure.

As illustrated in FIG. 5, a plurality of temperature measuring units 140 may be included to measure a temperature of each of regions CR, MR, and ER of a shower plate 110.

In addition, as illustrated in FIG. 5, a power supply 160, operating a planar heating element 150 as a heat dissipating element by supplying power to the planar heating element 150, and a controller 170, controlling a temperature of the planar heating element 150 through the power supply 160 based on the temperature measured by the temperature measuring unit 140, may be further included. That is, the controller 170 may control the power supply 160 to maintain a uniform temperature of the planar heating element 150.

The planar heating element 150 described above may operate as a heat conductor when power supply from the power supply 160 is cut off.

As described above, according to an example embodiment of the present disclosure, uniform temperature distribution of a showerhead may be controlled through a planar heating element instead of a heating member positioned on the outside of an electrostatic chuck.

In addition, according to an example embodiment of the present disclosure, the planar heating element may have excellent heat properties and dissipation thermal conductivity using graphene or a graphene-mixed material.

While example embodiments have been shown and described above, it will be apparent to those skilled in the art that modifications and variations could be made without departing from the scope of the present disclosure as defined by the appended claims.

What is claimed is:

1. A showerhead spraying a processing gas for treating a substrate into a treatment space of a processing chamber, the showerhead comprising:
a shower plate in which a plurality of spray holes are formed, the shower plate configured to spray a processing gas into the treatment space through the plurality of spray holes;
a lower plate installed on an upper side of the shower plate, the lower plate in which a plurality of spray flow paths, connected to the plurality of spray holes, are formed;
an upper plate installed on an upper side of the lower plate, the upper plate configured to spray the processing gas to the plurality of spray flow paths; and
a planar heating element configured to heat the processing gas sprayed through the shower plate.

2. The showerhead of claim 1, wherein the planar heating element is graphene or a graphene-mixed material.

3. The showerhead of claim 2, wherein the graphene-mixed material is a material in which graphene and graphite particles are mixed at a weight ratio of 1:2 to 8, and a size ratio of the graphene to the graphite particles is 1:30 to 2000.

4. The showerhead of claim 1, wherein the planar heating element has a thickness of 0.1 mm or more and 0.2 mm or less.

5. The showerhead of claim 1, wherein the planar heating element is provided in at least one of a space between the shower plate and the lower plate and a space between the lower plate and the upper plate.

6. The showerhead of claim 5, wherein the planar heating element has a shape corresponding to a shape of a surface on which the shower plate and the lower plate are in contact with each other or a shape corresponding to a shape of a surface on which the lower plate and the upper plate are in contact with each other.

7. The showerhead of claim 1, wherein
a plurality of through-holes are formed in the planar heating element, and
the number of the plurality of through-holes is formed to respectively correspond to the number of the plurality of spray holes or the plurality of spray flow paths.

8. The showerhead of claim 1, further comprising:
a power supply configured to operate the planar heating element as a heat dissipating element by supplying power to the planar heating element.

9. The showerhead of claim 8, further comprising:
at least one temperature measuring unit passing through the lower plate and the upper plate, the at least one temperature measuring unit installed on the shower plate, the at least one temperature measuring unit configured to measure a temperature of the shower plate.

10. The showerhead of claim 9, further comprising:
a controller configured to control, based on the temperature of the shower plate measured by the temperature measuring unit, a temperature of the planar heating element through the power supply.

11. The showerhead of claim 10, wherein the controller is configured to control the power supply to maintain a uniform temperature of the planar heating element.

12. The showerhead of claim 8, wherein the planar heating element is configured to operate as a heat conductor, when power supplied from the power supply is cut off.

13. The showerhead of claim 1, wherein a cooling flow path through which a refrigerant flows for preventing the shower plate from being heated to a temperature higher than or equal to a limit temperature is formed in the upper plate.

14. The showerhead of claim 13, wherein the cooling flow path is configured as a single flow path.

15. The showerhead of claim 14, wherein
the single flow path is formed to have a curved shape along an edge region of the upper plate in the edge region,
the single flow path is formed to have a circular shape along a boundary between the edge region and a middle region of the upper plate at the boundary,
the single flow path is formed to have a curved shape along the middle region of the upper plate in the middle region,
the single flow path is formed to have a circular shape along a boundary between the middle region and a center region of the upper plate at the boundary, and
the single flow path is formed to have a circular shape in the center region of the upper plate.

16. A showerhead spraying a processing gas for treating a substrate into a treatment space of a processing chamber, the showerhead comprising:
a shower plate in which a plurality of spray holes are formed, the shower plate configured to spray a processing gas into the treatment space through the plurality of spray holes;
a lower plate installed on an upper side of the shower plate, the lower plate in which a plurality of spray flow paths, connected to the plurality of spray holes, are formed;
an upper plate installed on an upper side of the lower plate, the upper plate configured to spray the processing gas to the plurality of spray flow paths;
a planar heating element configured to heat the processing gas sprayed through the shower plate;
a power supply configured to operate the planar heating element as a heat dissipating element by supplying power to the planar heating element;
at least one temperature measuring unit passing through the lower plate and the upper plate, the at least one temperature measuring unit installed on the shower plate, the at least one temperature measuring unit configured to measure a temperature of the shower plate; and
a controller configured to control, based on the temperature of the shower plate measured by the temperature measuring unit, a temperature of the planar heating element through the power supply,
wherein the planar heating element has a shape corresponding to a shape of a surface on which the shower plate and the lower plate are in contact with each other or a shape corresponding to a shape of a surface on which the lower plate and the upper plate are in contact with each other.

17. The showerhead of claim 16, wherein the planar heating element is a material in which graphene and graphite particles are mixed at a weight ratio of 1:2 to 8, and a size ratio of the graphene to the graphite particles is 1:30 to 2000.

18. The showerhead of claim 17, wherein the planar heating element has a thickness of 0.1 mm or more and 0.2 mm or less.

19. The showerhead of claim 16, wherein the planar heating element is configured to operate as a heat conductor, when power supplied from the power supply is cut off.

20. A substrate treatment apparatus comprising:
a processing chamber in which a treatment space is formed to treat a substrate;
a showerhead installed on an upper side of the treatment space in the processing chamber, the showerhead configured to spray a processing gas for treating the substrate into the treatment space; and
a substrate support installed on a lower side of the treatment space to vertically oppose the showerhead in the processing chamber, the substrate support on which the substrate is seated,
wherein the showerhead includes:
a shower plate in which a plurality of spray holes are formed, the shower plate configured to spray the processing gas into the treatment space through the plurality of spray holes;
a lower plate installed on an upper side of the shower plate, the lower plate in which a plurality of spray flow paths, connected to the plurality of spray holes, are formed;
an upper plate installed on an upper side of the lower plate, the upper plate configured to spray the processing gas to the plurality of spray flow paths; and
a planar heating element configured to heat the processing gas sprayed through the shower plate,
the planar heating element is graphene or a graphene-mixed material, and the graphene-mixed material is a material in which graphene and graphite particles are mixed at a weight ratio of 1:2 to 8, and a size ratio of the graphene to the graphite particles is 1:30 to 2000, and
the planar heating element is provided in at least one of a space between the shower plate and the lower plate and a space between the lower plate and the upper plate.
